(19) United States
(12) Patent Application Publication
(10) Pub. No.: US 2004/0250774 A1
(43) Pub. Date: Dec. 16, 2004

(54) Wafer heater with protected heater element

(76) Inventors: Brent Elliot, Cupertino, CA (US); Frank Balma, Monte Sereno, CA (US)

Correspondence Address: COOLEY GODWARD, LLP, 3000 EL CAMINO REAL, 5 PALO ALTO SQUARE, PALO ALTO, CA, 94306, US

(21) Appl. No.: 10/463,639

(22) Filed: Jun. 16, 2003

(51) Int. Cl. C23C 16/00

(52) U.S. Cl. 118/725; 156/345.52

(57) ABSTRACT

The present invention satisfies this and other needs by providing a novel wafer heater, which isolates a heater element from the vacuum environment. Thus, a non-aluminum heater element can be used in a wafer heater of the current invention. The novel wafer heater of the invention has an interface with high vacuum integrity, minimal dead space and reduced potential for vacuum contamination.

### 1. FIELD OF THE INVENTION

The present invention relates generally to equipment for semiconductor processing. More specifically, the present invention provides a novel wafer heater which isolates a heater element from a process environment.

### 2. BACKGROUND OF THE INVENTION

A critical factor in semiconductor processing is precise control of wafer temperature. For example, common semiconductor processes such as polysilicon deposition, molecular beam epitaxy, chemical vapor deposition and thermal annealing strongly depend on uniform wafer temperature. Accordingly, much effort has been expended on developing wafer heaters, which provide uniform temperatures at the wafer surface.

In general, a wafer beater performs a number of important functions in semiconductor processing. First, a wafer heater provides a vacuum port to hold a semiconductor wafer to a surface of the wafer heater. Second, a wafer heater prevents process gases from reacting with the backside of a wafer by providing a gas port, which may be used to purge corrosive gases with inert gases. Third, a wafer beater provides uniform heat to a semiconductor wafer, which is essential for conventional semiconductor processes. Fourth, a wafer heater provides an interface between the process environment and the external environment, which has high vacuum integrity.

In typical wafer heaters, the heater element is directly welded to the heater base, which is disadvantageous for several reasons. First, the heater element must be compatible with welding to aluminum, which necessitates using aluminum as the heater element. A heater element comprised of aluminum has a shorter lifespan than heater elements made of other materials and accordingly, reduces wafer heater lifetime. Second, welding of an aluminum heater element to the heater base introduces contaminants such as metals, metal oxides, carbon and other materials to the heater element, which significantly degrades wafer heater performance.

Another significant problem with existing wafer heaters is providing an interface with high vacuum integrity and minimal contamination. High integrity vacuum interfaces typically provide a seal with extremely low leak rates (typically, less than 1×10⁻⁹ cc of helium per second), minimal dead space (i.e., areas which are not swept by consistent gas flow) and diminished potential for contamination of the vacuum by trapped materials such as gases, particles or substances entrained on exposed surfaces.

Typically, in conventional wafer heaters, an aluminum heater element is welded directly to a heater base, a cap is welded over the heater element to the heater base and a stem, and the heater element is welded to the stem. However, this conventional design exposes the entire heater element and the groove in the heater base in which the heater element resides to the vacuum environment. Exposure of the substantial surface area of the heater element and the groove in the heater base to the vacuum environment greatly increases the dead space in existing wafer heaters. Further, contamination is often a serious problem in conventional wafer heaters since no gas flow is directed through the groove where the heater element contacts the heater base.

Accordingly, what is needed is a wafer heater which isolates a heater element from the vacuum environment, thus providing an interface with high vacuum integrity, minimal dead space and reduced potential for vacuum contamination. Preferably, the heater element is comprised of materials (i.e., non-aluminum materials) which do not contribute to heater failure.

### 3. SUMMARY OF THE INVENTION

The present invention satisfies this and other needs by providing a novel wafer heater, which isolates the heater element from the vacuum environment. Thus, a non-aluminum heater element can be used in a wafer heater of the current invention. The novel wafer heater of the invention has an interface with high vacuum integrity, minimal dead space and reduced potential for vacuum contamination.

In one aspect, the present invention provides a wafer heater comprising a heater base defining a wafer surface and an internal surface with a groove opposite the wafer surface, a heater element embedded in the groove of the heater base, which has two ends extending from the surface of the heater base, a heater cap in mechanical contact with the heater base and the heater element, which is attached to the heater base, a heater sheath defining a pair of conjoined hollow tubes, which is attached to the heater base with the ends of the heater element passing through the conjoined tubes and a stem attached to the heater base and the conjoined tubes of the heater sheath. The heater base has at least one channel for vacuum and at least one channel for gas with the channels extending through the heater base from the wafer surface to the internal surface. The stem also has at least one vacuum port, at least one gas port and two heater sheath ports.

In one embodiment, the heater base is stainless steel, nickel, inconel or aluminum. Preferably, the heater base is aluminum.

In another embodiment the heater element is a resistance type heater. In still another embodiment, the heater element is inconel, stainless steel, incoloy or aluminum. Preferably, the heater element is incoloy.

In still another embodiment, the heater cap is inconel, stainless steel, incoloy or aluminum. Preferably, the heater cap is aluminum. In still another embodiment, the heater cap is welded to the heater base.

In still another embodiment, the heater sheath is selected from the group consisting of inconel, stainless steel, incoloy and aluminum. Preferably, the heater sheath is aluminum. In still another embodiment, the heater sheath is welded to the heater base and heater cap.

In still another embodiment, the stem is inconel, stainless steel, incoloy or aluminum. Preferably, the stem is aluminum. In still another embodiment, the stem is welded to the heater base and the heater sheath. In still another embodiment, the heater base, heater sheath, heater cap and stem isolate the heater element from the process environment.

In another aspect, the present invention provides a wafer heater with a heater base, a heater element, a heater cap, a heater sheath and a stem, where the heater base, heater cap, heater sheath and stem isolate the heater element from the process environment.

In still another aspect, the present invention provides a method of making a semiconductor wafer comprising using a wafer heater of the present invention.

### 4. BRIEF DESCRIPTION OF THE DRAWINGS

FIG. 1 illustrates a surface of a heater base, which has an embedded groove;

FIG. 2 illustrates the wafer surface of the heater base;

FIG. 3 illustrates a heater element;

FIG.4 illustrates the heater element embedded in the groove of the heater base;

FIG. 5 illustrates a heater cap;

FIG. 6 illustrates the heater cap in mechanical contact with the heater element and heater base;

FIG. 7 illustrates a heater sheath;

FIG. 8 illustrates the heater cap in mechanical contact with the heater element and heater base with the heater sheath attached to the heater base and heater cap with the ends of the heater element passing through the conjoined tubes of the heater sheath;

FIG. 9 illustrates a stem; and

FIG. 10 illustrates an exemplary wafer heater of the current invention.

### 5. DETAILED DESCRIPTION OF THE INVENTION

Reference will now be made in detail to preferred embodiments of the invention as illustrated in the accompanying drawings. While the invention will be described in conjunction with particular embodiments, it will be understood that it is not intended to limit the invention to those specific embodiments. Numerous specific details are set forth to provide a thorough understanding of the present invention. Accordingly, the skilled artisan will appreciate that the present invention may be practiced without some or all of these specific details and includes alternatives, modifications and equivalents within the scope of the invention as defined by the appended claims.

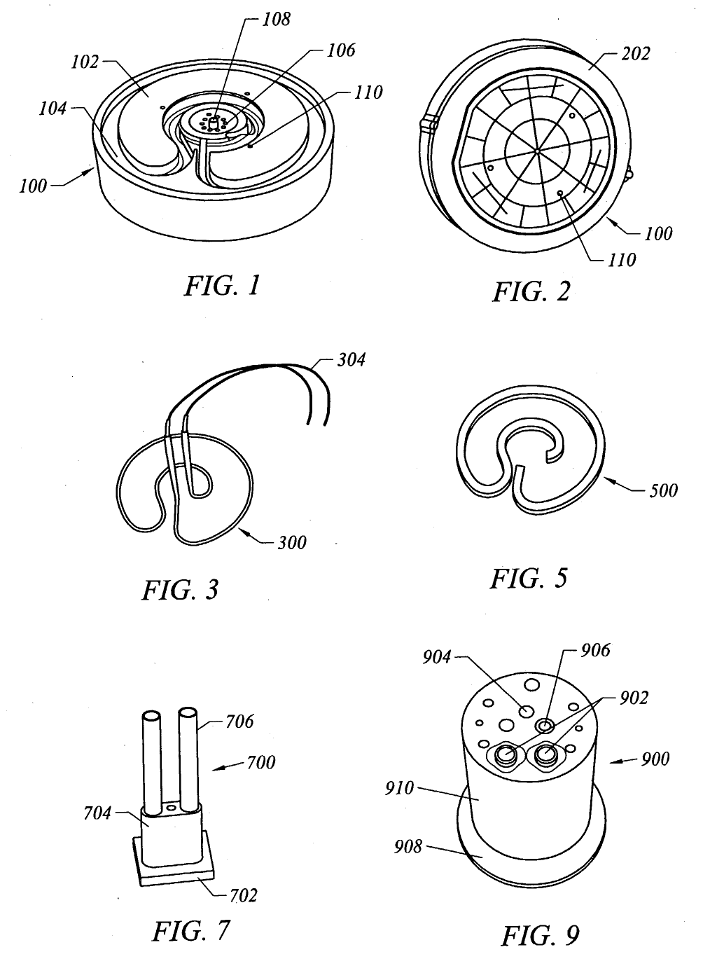

FIG. 1 illustrates a surface 102 of heater base 100 useful in the present invention. The heater base may be stainless steel, nickel, inconel, aluminum or combinations thereof. Preferably, the heater base is aluminum. A groove 104 is formed in surface 102 of heater base 100 by conventional methods known to the skilled artisan. The serpentine pattern and depth of groove 102 illustrated in FIG. 1 are exemplary and many different combinations of patterns and groove depths may be advantageously used in the present invention. Ports 106 may be used to deliver inert gas to various locations of heater base 100. Vacuum port 108, may extend through the heater body and provides a mechanism for attaching the wafer backside to the opposite surface of the heater body by application of vacuum. Finally, lift pin holes 110, which typically extend through the heater body, are for lift pin clearance.

FIG. 2 illustrates the opposite surface 202 of heater base 100, to which the wafer is attached. The figure also illustrates holes 110, through which lift pins can pass. The exact dimensions and shape of heater base 100 will typically vary with wafer size and shape.

FIG. 3 illustrates an exemplary heater element 300 of the present invention.

Electrical leads 304 are attached to heater element 300 to provide a conventional resistance type heater. Heater element 300 may be inconel, stainless steel, incoloy, aluminum or combinations thereof. Preferably, the heater element is incoloy. An advantage of the current invention is the possibility of using non-aluminum heater elements, which typically have longer service lifetimes than aluminum heater elements.

FIG. 4 illustrates heater element 300 embedded in groove 104 of heater base 100. The shape of heater element 300 will typically match the pattern of groove 104 formed in the surface of heater base 100. As previously noted, many different groove 20 patterns may be advantageously used in the present invention. Application of electrical current to heater element 300 through attached electrical leads 304 transfers heat to the wafer through heater base 100. The uniformity of heat conducted to the wafer surface is determined by the exact location of the heater element in the heater base, the pattern of the heater element and the distance of the heater element from the wafer surface. In a wafer heater of the current invention, the latter two factors may be controlled by the depth and pattern of groove 104 embedded in heater base 100.

FIG. 5 illustrates an exemplary heater cap 500 of the current invention. The shape of heater cap 500 will typically match the pattern of the groove and heater element. The heater cap may be inconel, stainless steel, incoloy, aluminum or 30 mixtures thereof. Preferably, the heater cap is aluminum.

FIG. 6 illustrates heater cap 500 in mechanical contact with heater element 300 and heater base 100. Heater cap 500 covers the portion of heater element 300, which is embedded in the groove of heater base 100, thus shielding this part of heater element 300 from the process environment. As can be seen in FIG. 6, the portion of heater element 300, that protrudes from the surface of heater base 100 is not covered by heater cap 500. Heater cap 500 may be attached to heater base 100 by welding or brazing, which secures the location and clearance of beater element 300 within heater base 100 and the heater cap 500. The pattern of heater element 300 and clearances between the heater base 100, heater element 300 and heater cap 500 combine to provide uniform temperature (±4%) at the wafer surface. Many different combinations of patterns and clearances may be used to achieve the same temperature uniformity, as is well known to the skilled artisan.

One of the advantages of the present invention is that the heater element 300 need not be welded or brazed directly to the wafer heater. Instead, the heater cap 500 maintains mechanical contact between heater element 300 and heater base 100. Thus, an advantage of the invention is that compatibility with aluminum welding is not required.

FIG. 7 illustrates an exemplary heater sheath 700 useful in the present invention. Heater sheath 700 consists of a pair of conjoined hollow tubes 706 attached to sheath body 704, which is joined to sheath base 702. The heater sheath may be inconel, stainless steel, incoloy, aluminum and combinations thereof. Preferably, the heater sheath is aluminum.

It should be specifically noted that the present invention is not restricted to heater sheaths with conjoined hollow tubes. as illustrated in FIG. 7. In one embodiment, the hollow tubes are completely separated and are independently welded or brazed to the heater base and heater cap.

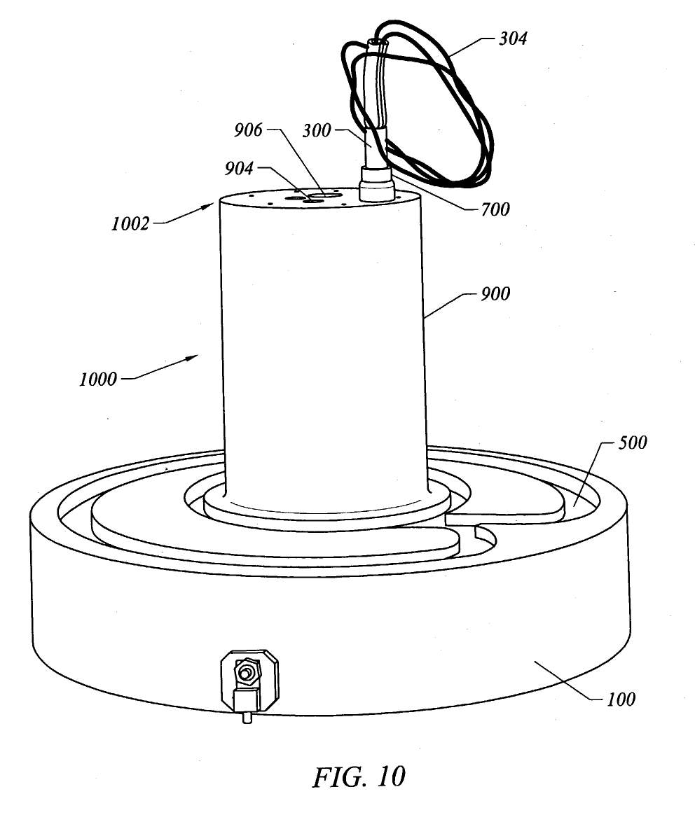

The heater sheath, through which the heater element passes, is welded or brazed at one end to the heater base and cap, and at the other end to the stem (See FIG. 10). Accordingly, the heater sheath isolates the heater element from the vacuum environment, which substantially reduces dead space and potential for contamination. An important advantage of the present invention is the significant improvement in vacuum integrity provided by using the heater sheath in isolating the heater element.

FIG. 8 illustrates heater cap 500 in mechanical contact with heater element 300 and heaterbase 100. Heater sheath 700 is attached to heater base 100 and heater cap 500 with heater element 300 passing through conjoined tubes 706 of heater sheath 700. Electrical leads 304 are attached to heater element 300. Heater sheath 700 may be attached to heater base 100 and heater cap 500 by welding or brazing.

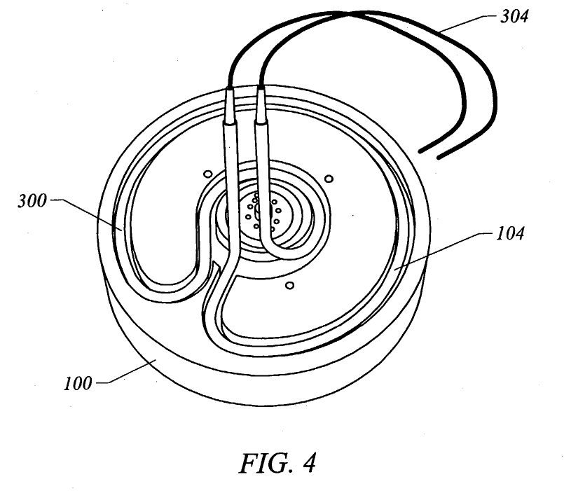

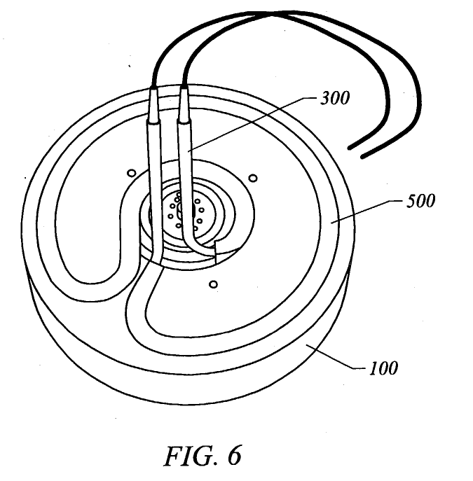

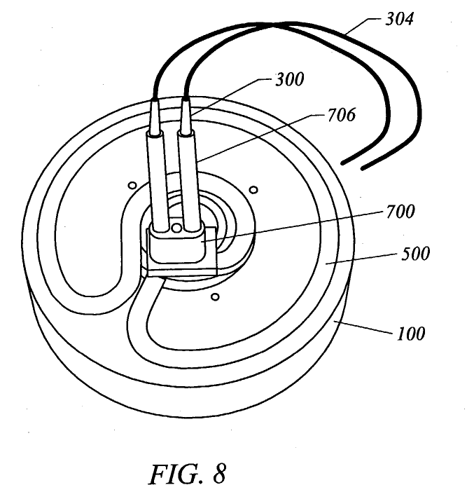

FIG. 9 illustrates an exemplary stem 900, useful in the present invention. Stem 900 has stem base 908 and stem body 910. On the top surface of stem 900 are apertures for vacuum (e.g., 906), gas (e.g., 904) and the conjoined tubes of the heater sheath (e.g., 902). The stem may be inconel, stainless steel, incoloy, aluminum or combinations thereof. Preferably, the stem is aluminum.

FIG. 10 illustrates an exemplary wafer heater 1000 of the current invention. Heater cap 500 is in mechanical contact with the heater element 300 (not shown at point of contact) and heater base 100. Heater sheath 700 is attached to heater base 100 and heater cap 500. Heater element 300 passes through conjoined tubes of heater sheath 700. Electrical leads 304 are attached to heater element 300. The conjoined tubes of heater sheath 700 protrude through stem 900. Stem 900 may be attached to heater base 100 and heater sheath 700 by welding or brazing. Vacuum ports 906 and purge gas ports 904 are located at the top of stem 900. Attachment of stem 900 to heater sheath 700 and heater base 100 provides significant improvement in integrity of vacuum interface 1002 by completely isolating heater element 300 and its associated groove in heater base 100 from the vacuum environment. Isolation also extends the lifetime of wafer heater 1000 by preventing corrosion of heater element 300. Further extending the lifetime of wafer heater 1000 is the ability to employ a heater element made of inconel, incoloy, or stainless steels, which has a substantially greater lifetime than a heater elements made of aluminum.

Wafer heater 1000 provides purge gas and vacuum to a semiconductor wafer utilizing standard methods known to those of skill in the art. Vacuum, which helps clamp the wafer to wafer heater 1000 may be provided through dedicated ports 906 on stem 900, which are connected to heater base 100. For example, vacuum may be conducted through heater base 100 via a series of channels and holes and distributed evenly across the wafer side of heater base 100 via a series of radial and concentric grooves, as shown in FIG. 2. Purge gas may be provided to the wafer backside from dedicated ports 904 located on the top surface of stem 900. Purge gas may flow through a common plenum area interior to stem 900, through a series of channels and ports to heater base 100 and to the wafer edge via a groove on the wafer surface. Numerous other methods for accomplishing the above functions exist and may be utilized in a wafer heater of the present invention.

It should be noted the wafer heater of the invention may be assembled by welding or brazing of the components. In particular, brazing is preferred when components are made of different materials.

Further, it is envisioned that the wafer heater of the current invention may be generally used in semiconductor processing to make diverse types of semiconductor wafers. Accordingly, use of the wafer heater of the current invention is not restricted to making a particular semiconductor wafer or to the practice of a specific semiconductor process.

Finally, it should be noted that there are alternative ways of implementing the present invention. For example, the shape and appearance of the components of the wafer heater could be different than those described above or the components could be assembled by a method not described herein. In general, a wafer heater of the invention isolates the heater element and its associated groove from the vacuum environment. More specifically, a wafer beater of the invention will typically have a heater base, a heater element, a heater cap, a heater sheath and a stem where the heater cap, heater sheath and stem isolate the heater element from the process environment. The ability to use a heater element of non-aluminum material is another important feature of a wafer heater of the present invention as is the ability to avoid welding the heater element to the heater base. Accordingly, the present embodiments are to be considered as illustrative and not restrictive, and the invention is not to be limited to the details given herein, but may be modified within the scope and equivalents of the appended claims.

What is claimed is:

1. A wafer heater comprising:
a heater base defining:
a wafer surface;
an internal surface with a groove opposite the wafer surface;
at least one channel for vacuum; and
at least one channel for gas;
said channels extending through the heater base from the wafer surface to the internal surface;
a heater element embedded in the groove of the heater base, said heater element having two ends extending from the surface of the heater base;
a heater cap in mechanical contact with the heater base and the heater element, said heater cap attached to the heater base;
a heater sheath defining a pair of conjoined hollow tubes, said heater sheath attached to the heater base with the ends of the heater element passing through the conjoined tubes; and
a stem defining:
at least one vacuum port;
at least one a gas port; and
two heater sheath ports;
said stem attached to the heater base and the conjoined tubes of the heater sheath.

2. The wafer heater of claim 1, wherein the heater base is selected from the group consisting of stainless steel, nickel, inconel and aluminum.

3. The wafer heater of claim 1, wherein the heater base is aluminum.

4. The wafer heater of claim 1, wherein the heater element is a resistance type heater.

5. The wafer heater of claim 1, wherein the heater element is selected from the group consisting of inconel, stainless steel, incoloy and aluminum.

6. The wafer heater of claim 1, wherein the heater element is incoloy.

7. The wafer heater of claim 1, wherein the heater cap is selected from the group consisting of inconel, stainless steel, incoloy and aluminum.

8. The wafer heater of claim 1, wherein the heater cap is aluminum.

9. The wafer heater of claim 1, wherein the heater cap is welded to the heater base.

10. The wafer heater of claim 1, wherein the heater sheath is selected from the group consisting of inconel, stainless steel, incoloy and aluminum.

11. The wafer heater of claim 1, wherein the heater sheath is aluminum.

12. The wafer heater of claim 1, wherein the heater sheath is welded to the heater base and heater cap.

13. The wafer heater of claim 1, wherein the stem is selected from the group consisting of inconel, stainless steel, incoloy and aluminum.

14. The wafer heater of claim 1, wherein the stem is aluminum.

15. The wafer heater of claim 1, wherein the stem is welded to the heater base and the heater sheath.

16. The wafer heater of claim 1, wherein the heater base, heater sheath, heater cap and stem isolate the heater element from the process environment.

17. A wafer heater comprising a heater base, a heater element, a heater cap, a heater sheath and a stem, wherein the heater base heater cap, heater sheath and stem isolate the heater element from a process environment.

18. A method of making a semiconductor wafer comprising using the wafer heater of claim 1.
